(19) United States
(12) Patent Application Publication
(10) Pub. No.: US 2014/0340853 A1
(43) Pub. Date: Nov. 20, 2014

(54) Safety Device

(71) Applicant: Infineon Technologies AG, Neubiberg (DE)

(72) Inventors: Timo Dittfeld, Muenchen (DE); Peter Hoffmann, Klagenfurt (AT); Dirk Hammerschmidt, Villach (AT)

(73) Assignee: Infineon Technologies AG, Neubiberg (DE)

(21) Appl. No.: 13/894,139

(22) Filed: May 14, 2013

(51) Int. Cl. H05K 7/04; H05K 3/20

(52) U.S. Cl. CPC H05K 7/04; H05K 3/20
USPC 361/748; 29/831

(57) ABSTRACT

Safety devices are provided having a power generating part and a safety-critical part. A conducting ring is provided at least around the power generating part. The ring may be connected to a reference potential such as ground.

### TECHNICAL FIELD

The present application relates to safety devices, for example, devices usable for triggering safety equipment.

### BACKGROUND

Safety equipment is used to prevent or reduce adverse effects of a safety-critical situation in many instances. For example, in the automotive industry airbags are used to reduce injuries in case of car accidents. Safety devices are used to trigger such safety equipment. For example, in the case of airbags, such a safety device may receive sensor signals, for example, sensor signals from acceleration sensors, and may trigger a firing, e.g., deployment, of the airbag in case the sensor signal indicates a safety-critical situation like an accident.

For safety reasons, conventionally different components of such a safety device were often implemented as separate chips. For example, a power supply may be provided on a different chip than a circuit finally triggering the airbag or other safety equipment. For costs reasons, however, in some cases it may be desirable to integrate some or all of the components of the safety device on a single chip. For example, all components apart from a microcontroller may be implemented on a single chip in some cases.

When, for example, a power supply or other power generating part and a triggering or firing unit that generates the signal that eventually causes deployment of the safety equipment are provided on a single chip, there is a danger that in case of a failure in the power generating part of the chip a high current may reach the triggering part via a common substrate (for example, a semiconductor wafer or a layer provided on a semiconductor wafer). This in turn may lead to an accidental triggering of the safety equipment, which in itself may be a safety hazard.

### BRIEF DESCRIPTION OF THE DRAWINGS

FIG. 1 is a schematic diagram of a safety device according to an embodiment;

FIG. 2 is a flowchart illustrating a method according to an embodiment;

FIG. 3 is a schematic diagram of a device according to an embodiment;

FIG. 4 is a schematic cross-sectional view of a device according to an embodiment; and

FIG. 5 is a schematic circuit diagram of a device according to an embodiment.

### DETAILED DESCRIPTION OF ILLUSTRATIVE EMBODIMENTS

In the following, various embodiments will be described in detail referring to the attached drawings. These embodiments merely serve as illustrative implementation examples and are not to be construed as limiting. For example, while embodiments may be described as having a plurality of features, other embodiments may have different features, for example, less features, alternative features or more features compared to a described embodiment. While for some embodiments specific numerical values, circuit diagrams, structural diagrams and the like are given, other embodiments may deviate from these examples. Various parts of the figures are not necessarily to scale with each other, but the drawings rather are provided to give a clear understanding of the respective embodiment. Furthermore, features from different embodiments may be combined with each other unless noted otherwise.

In some embodiments, a power generating part, for example a power supply, is implemented, e.g., on a same chip as a safety-critical part. In some embodiments, a conductive ring is formed surrounding at least the power generating part, e.g., surrounding both the power generating part and the safety-critical part in some embodiments. In some embodiments, the power generating part is separated from the safety-critical part by a predetermined minimum safety distance, which may, for example, significantly exceed a distance between the power generating part and the above-mentioned ring. The ring may be coupled with a voltage potential, such as, ground via one or a plurality of connections, such as bond wires. The safety-critical part may, for example, be a part configured to output a triggering or firing signal to safety equipment, such as an airbag.

In some embodiments, when a power surge to the substrate occurs in the power generating part, this power surge is deviated via the above-mentioned ring to ground, and at most a small part of the power surge reaches the safety-critical part such that the power surge does not cause the safety-critical part to trigger the safety equipment.

While the power generating part may be a power source, generally the power generating part may be any part which due to a malfunction may generate a power surge which, without additional measures such as the above-mentioned ring, may potentially cause the safety-critical part to trigger the safety equipment.

Generally, in the context of this disclosure the term “safety equipment” relates to an apparatus that when triggered decreases, mitigates or removes adverse effects of a safety-critical situation, such as an airbag, other automotive safety equipment, sprinkler fire extinguishing installations, to name just a few. A safety device is used herein to refer to the circuitry used for triggering the safety equipment, for example, by evaluating corresponding sensor signals. While in the following safety devices for triggering airbags are used in many embodiments as illustrative examples, the concepts and techniques described herein may also be applied to other safety equipment and safety devices, for example, the ones mentioned above.

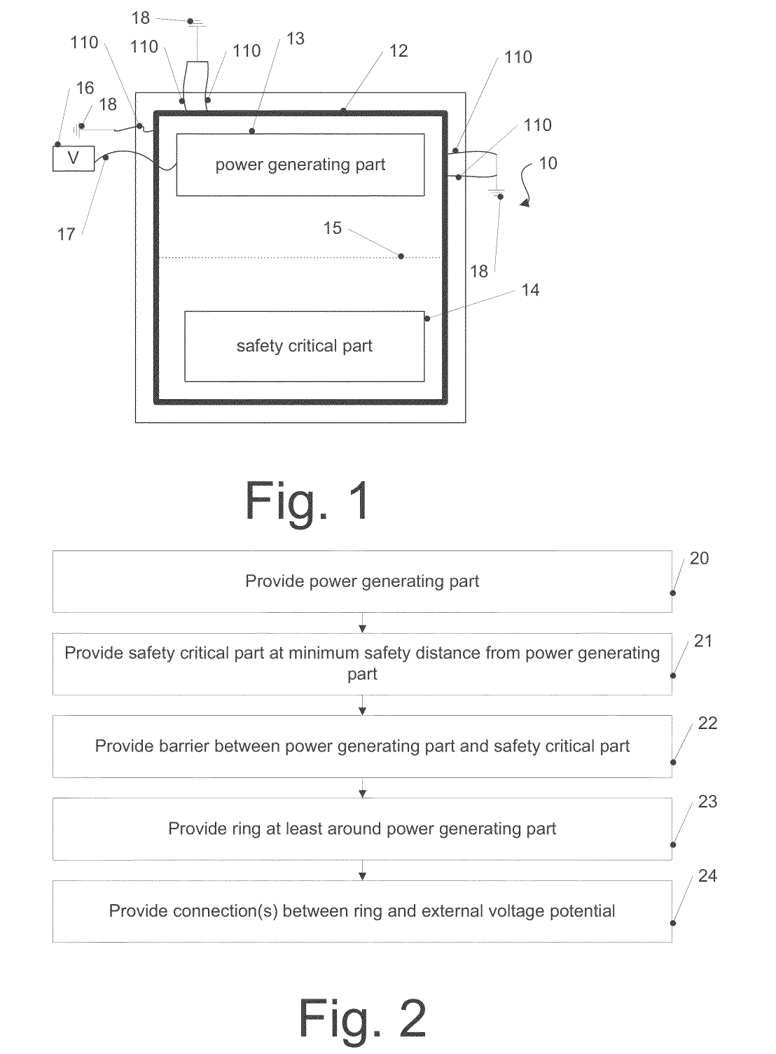

FIG. 1 shows a safety device 10 according to an embodiment. Safety device 10 comprises a power generating part 13, for example, a power supply, and a safety-critical part 14, for example, an airbag triggering circuit, sometimes also referred to as airbag firing circuit, or another circuit which outputs a signal for triggering safety equipment. An accidental triggering of such safety equipment is often to be avoided. For example, deploying an airbag of a car in a normal driving situation may lead to an accident.

In safety device 10 of the embodiment of FIG. 1 power generating part 13 and safety-critical part 14 are implemented on a same chip, for example, sharing a same silicon substrate.

In some embodiments, power generating part 13 and safety-critical part 14 may be separated by a separation 15, for example, a deep trench in the substrate filled, for example, with insulating material, for example, a silicon oxide, or with semiconductor material having an opposite doping polarity (p versus n or n versus p) compared to a surrounding substrate. As will be explained further below using examples, such a barrier may increase a resistance for a path from power generating part 13 to safety-critical part 14 via the substrate.

Power generating part 13 is coupled with an external voltage source 16 such as a battery via a bond wire 17. Power generating part 13 for example may generate various voltages to be used within safety device 10.

Furthermore, safety device 10 comprises a ring 12 surrounding power generating part 13 and safety-critical part 14. Ring 12 may, for example, comprise a trench filled with a conducting material such as a metal, for example, copper.

Ring 12 is coupled with an external reference potential, such as ground 18, via a plurality of connections 110, for example, bond wires.

In some embodiments, the number of connections or bond wires connecting ring 12 to ground 18 is greater than, for example, at least twice the number of connections 17 connecting power generating part 13 to external voltage source 16.

In some embodiments, power generating part 13 and safety-critical part 14 are spaced apart a minimum predetermined safety distance. The safety distance may, for example, be chosen such that a resistance for a current path from power generating part 13 to safety-critical part 14 via a common substrate is significantly greater than a resistance of a current path from power generating part 13 to ring 12. For example, the resistance may be at least two times greater, at least five times greater, at least ten times greater or at least one hundred times greater. The differences in resistance may in part be due to barrier 15 and/or the above-mentioned predetermined minimum safety distance.

In some embodiments, in the case of an inadvertent power surge from power generating part 13 to the substrate (e.g., shunting external voltage source 16 to the substrate), the largest part of the power surge is deviated via ring 12 and connections 110 to ground 18, and only a small portion of the power surge reaches safety-critical part 14, in particular a portion that is so small that a corresponding safety equipment is not triggered. In embodiments where the number of connections 110 exceeds the number of connections 17, in such a power surge, for example, connection 17 may melt, thus providing a safety fuse function.

FIG. 2 shows a flowchart illustrating a method according to an embodiment. While the method is depicted as a series of acts or events, the order in which these acts or events are shown and described is not to be construed as limiting. For example, in various acts or events various elements or blocks of a device are provided, and unless noted otherwise these devices may be provided in any desired order or concurrently with each other. For example, elements of a power generating part and of a safety-critical part may be implemented on a silicon wafer in the same or partly the same processing during manufacture.

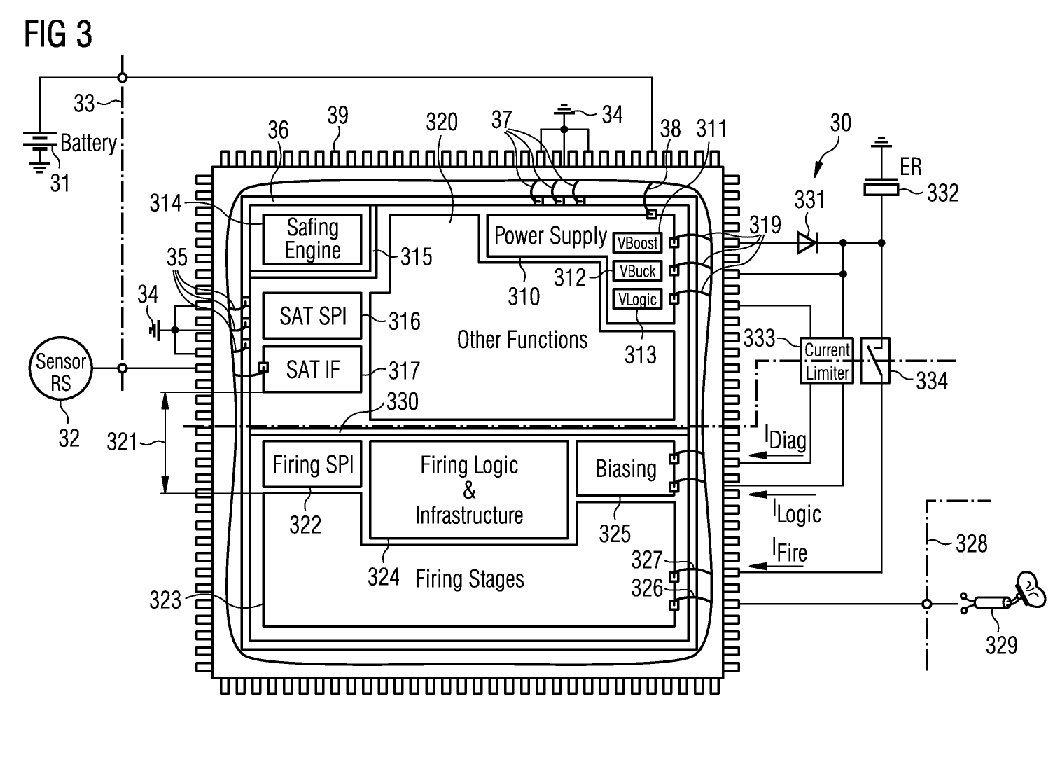

The method of FIG. 2, or variations thereof, may for example be used for manufacturing the embodiment of FIG. 1 described above or any of the embodiments of FIGS. 3-5 to be described later. This method may also be used to manufacture other embodiments and devices.

At 20, a power generating part, such as a power source, is provided on a substrate, for example, a silicon wafer.

At 21, a safety-critical part, for example, comprising circuitry for triggering safety equipment, is provided on the substrate, e.g., at a minimum safety distance or more from the power generating part of the substrate.

At 22, optionally a barrier, e.g., comprising a trench, is provided between the power generating part and the safety-critical part.

At 23, a ring made of a conductive material is provided at least around the power generating part and in some embodiments, for example, for manufacturing the device 10 of FIG. 1, around both the power generating part and the safety-critical part.

At 24 one or more connections, for example, a plurality of bonding wires, are provided between the ring and an external voltage potential like ground.

A thus manufactured device may prevent a power surge to the substrate generated due to a failure in the power generating part from reaching the safety-critical part with a strength sufficient to trigger an undesired function of the safety-critical part, e.g., triggering of safety equipment.

FIG. 3 shows a safety device 30 according to an embodiment. The device 30 is implemented as a chip within a package having a plurality of pins 39. While a single chip is shown in the embodiment of FIG. 3, in other embodiments more than one chip may be provided within a single package.

Safety device 30 may be used as a safety device for triggering an airbag 329 based on signals from a sensor 32, for example, an acceleration sensor.

The chip shown is partitioned into three major parts by trenches 315 and 330, which may, for example, be filled with an insulating material or a semiconductor material. In a first part delimited by trench 315, a safing engine 314 is provided. Generally, a safing engine is used to provide path for evaluating a sensor signal or other signal and for deciding if safety equipment is to be triggered, in this case if airbag 329 is to be fired. To this end, in the embodiment of FIG. 3, safing engine 314, upon deciding that a safety-critical situation occurs, may close a safing switch 343, thus enabling a firing of the airbag as will be described later. For example, safing engine 314 may receive a signal from an optical sensor like an OBS sensor (Optical Backscatter Point sensor) and perform the above-described evaluation based on the signal from the optical sensor.

A second part is delimited by trench 315 and trench 330 and comprises several elements, for example, a satellite interface (SAT IF) 317, a satellite serial peripheral interface (SAT SPI) 316, a block 320 implementing various other functions, for example, evaluating signals from interfaces 316, 317 and a power supply 310. For example, satellite interface 317 may be connected to sensor 32 via a corresponding pin 39 and a bonding wire to receive signals therefrom, and block 320 may then evaluate these signals.

In the embodiment shown, power supply 310 comprises a boost converter 311 to provide a first voltage, a buck converter 312 to provide a second voltage and a linear voltage source 313 to provide a voltage, e.g., for logic circuits such as a firing logic 324, which will described later. In particular, boost converter 311 may provide a high voltage eventually triggering a firing of airbag 329. Power supply 310 is supplied by an external voltage source 31 via a respective pin 39 and a bonding wire 38 as shown.

Boost converter 311, buck converter 312 and linear voltage source 314 are coupled with respective pins via bonding wires 319. A voltage generated by boost converter 311 is supplied via a diode 331 to safing switch 334. Additionally, an energy reservoir 332 is coupled to safing switch 334. Energy reservoir 332, e.g., comprising an electrolytic capacitor, may provide energy in some situations where due to an accident, e.g., external voltage source 31 is decoupled from device 30. When closed, via safing switch 334 a current is delivered to a firing stage 332 of a third part to be described later which eventually is used to generate a fire signal to airbag 329 firing, e.g., deploying, airbag 329. Elements 311, 312 and 313 in the embodiment of FIG. 3 are arranged comparatively close to ring 36.

Furthermore, the voltages generated by buck converter 312 and by linear voltage source 313 are supplied to a biasing block 325 via a current limiter 333. Current limiter 333 prevents an excessive current from reaching the third part of the chip, the third part being limited by trench 330 and comprising the already mentioned firing logic and infrastructure 324, biasing block 325, firing stages 323 and a firing serial peripheral interface (firing SPI) 322.

Biasing block 325 may provide biasing voltages for example for firing stages 323 and firing logic and infrastructure 324 may provide signals to firing stages 323 to trigger a regular firing, for example, depending on signals received via firing serial peripheral interface (SPI) 322, e.g., from block 320.

Firing stages 323 are an example for a safety-critical part, while, for example, power supply 310 or other components of the second part of the chip like SAT IF 317 may serve as an example for power generating parts. Firing stages 323 in the embodiment of FIG. 3 are arranged in a predetermined minimum safety distance 321 or more from such power generating parts.

Voltage source 31 and sensor 32 may be coupled to safety device 30 via an interface 33, and airbag 329 may be coupled to safety device 30 via an interface 328.

The various components and parts of the chip discussed above are surrounded by a ring 36, which may be a conductive ring coupled to the substrate. Ring 36 is coupled to ground 34 at various places via bonding wires 35 and 37. More or less connections to ground and/or connections to ground at different places may also be provided. When in the second part of the chip, for example, due to a breakthrough of a substrate diode in case of electrical overcharge, a voltage from voltage source 31 is coupled to the substrate of the chip, such a power surge is deviated via ring 36 to ground 34, and only a small amount of the power surge may reach firing stages 324, such a small amount not being sufficient to trigger a firing of airbag 329. In the embodiment of FIG. 3, voltage source 31 is coupled to power supply 310 via a single bonding wire 38, while ring 36 is coupled to ground via a greater number of bonding wires, in the example shown six bonding wires 35, 37. Therefore, in case a high current flows during a power surge to the substrate, there is a comparatively high likelihood that bonding wire 38 (and not bonding wires 35, 37) will melt, thus effectively decoupling voltage source 31 from device 30, which effectively provides the function of a safety fuse.

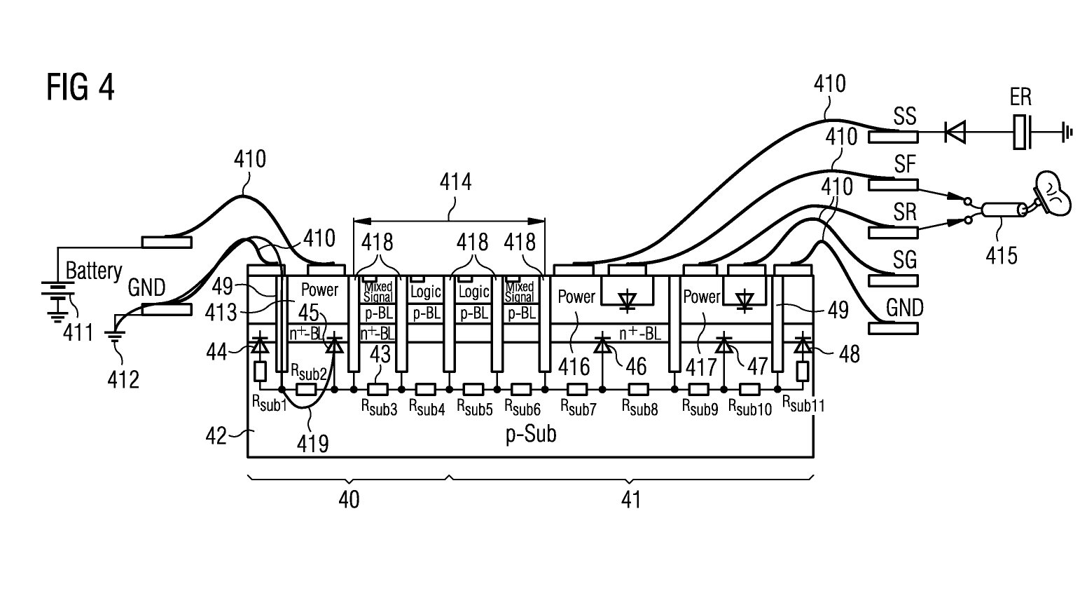

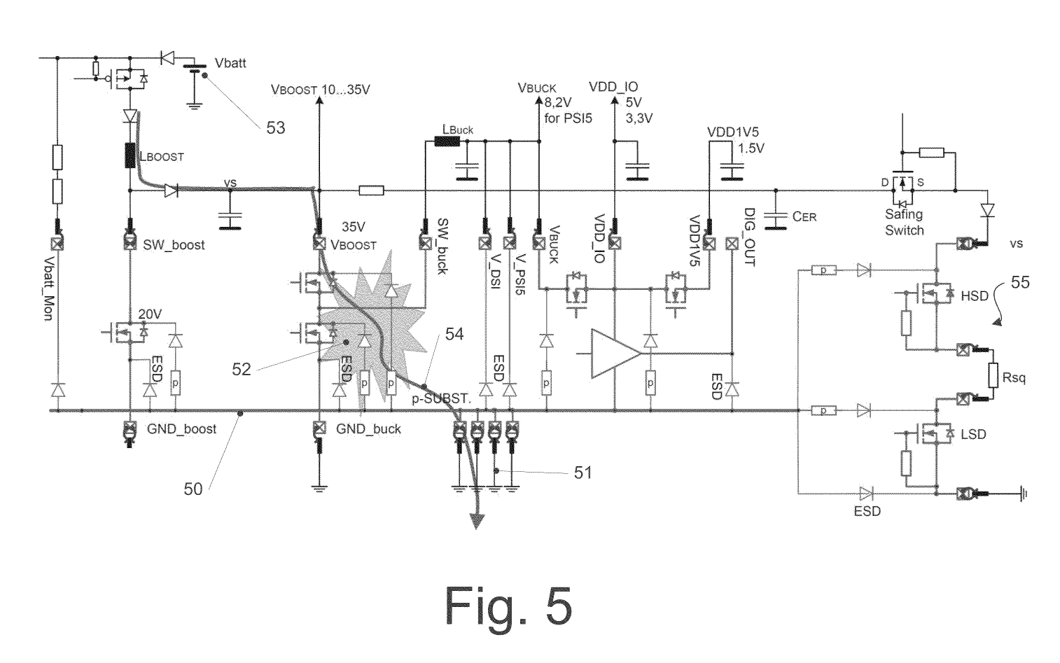

FIG. 4 shows a cross-sectional view of a further embodiment. FIG. 4 may serve as an illustrative example how parts of the embodiment of FIG. 1 or the embodiment of FIG. 3 may be implemented. In FIG. 4, a substrate 42, for example, a silicon substrate, is shown where various functional blocks, for example, blocks as shown in FIG. 3 or as shown in FIG. 1, are implemented. The various functions implemented are shown in a schematic way, and the implementation of the individual blocks may be performed in any conventional manner.

In particular, a power supply 412 is implemented on substrate 42 and coupled to an external voltage source 411 via a bond wire 410. Furthermore, firing stages 416, 417 are implemented on substrate 42 separated by a safety distance 414 from power supply 413. Within safety distance 414, other elements like logic blocks may be implemented on substrate 42, which are only schematically shown. Firing stages 416, 417 are coupled with an airbag 415 as shown. A ring 49 surrounds the various blocks and extends from a surface into substrate 42. Ring 49 may be made of a conductive material, for example, may comprise a trench filled with a metal like copper. Furthermore, various blocks shown are separated by insulating trenches 418.

Resistors 43 symbolize substrate resistances, i.e., they are not to be seen as specifically implemented resistances, but represent the resistance of the substrate.

Ring 49 is coupled with ground 412 via a plurality of bond wires 410.

To insulate the various blocks and components from substrate 42, p-n-junctions symbolized as substrate diodes 44 through 48 are provided. In the case of a breakthrough of, for example, substrate diode 45, for example, due to electrical overstress (EOS), a power surge generated is deviated to ground as schematically shown as a line 419 via ring 449. Due to the high substrate resistance between power source 413 and firing stages 416, 417, the path as symbolized by line 419 has a significantly lower resistance than a path from power supply 413 via substrate 42 to firing stages 416, 417. Therefore, the greatest part of the power surge is deviated to ground, and a part of the power surge which may still reach fire stages 416, 417 is not sufficient to trigger firing of airbag 415.

In FIG. 5, a schematic circuit diagram of a safety device according to an embodiment is shown. The circuit diagram of FIG. 5 may for example be implemented using principles as discussed with reference to FIG. 3 or 4 or may be implemented in a different manner.

The circuit of FIG. 5 comprises a voltage source comprising a boost converter and a buck converter supplied by an external voltage source 53 and configured to generate an internal voltage Vboost and an internal voltage Vbuck. Furthermore, the circuit diagram shows a firing stage 55 to trigger activation of an airbag. A ring, as explained above with reference to FIGS. 1, 3 and 4, is shown as a rail 50 in FIG. 5. When a failure occurs, for example, a breakthrough of substrate diodes, as symbolized by a star 52 within the buck converter, a power surge based on the voltage from external voltage source 53 is deviated to ground via a plurality of connections 51 between ring 50 and ground, as symbolized by a path 54. A portion of the power surge reaching firing stage 55, in contrast thereto, is not sufficient to trigger a firing of the airbag.

While a plurality of specific details, circuit blocks, circuitry and structures have been shown in the preceding embodiments, for example, the embodiments of FIGS. 3, 4 and 5, these serve for illustration purposes only and are not to be construed as limiting. For example, other safety-critical parts than firing stages for an airbag or other power generating parts than the power supplies shown may be used. Other blocks, for example logical blocks, biasing blocks and interfaces as, for example, depicted in FIG. 3, may be provided depending on the requirement of the respective application, and the blocks and elements shown serve only as illustrative examples.

What is claimed is:

1. A device, comprising:
a substrate;
power generating circuitry provided on the substrate;
safety-critical circuitry provided on the substrate; and
a conductive ring surrounding the power generating circuitry.

2. The device of claim 1, wherein the ring comprises a metal.

3. The device of claim 1, further comprising a barrier between the power generating circuitry and the safety-critical circuitry.

4. The device of claim 3, wherein the barrier comprises a trench.

5. The device of claim 1, wherein the ring is coupled to an external reference potential.

6. The device of claim 5, wherein the external reference potential is a ground potential.

7. The device of claim 5, wherein the power generating circuitry is coupled to an external voltage source by a first number of couplings and the ring is coupled to the external reference potential by a second number of couplings, wherein the first number of couplings is less than the second number of couplings.

8. The device of claim 7, wherein the couplings comprise bond wires.

9. The device of claim 1, wherein the safety-critical circuitry is configured to trigger deployment of safety equipment.

10. The device of claim 1, wherein the power generating circuitry comprises a power source.

11. The device of claim 1, wherein the power generating circuitry is separated from the safety-critical circuitry by a distance such that a substrate resistance between the power generating circuitry and the safety-critical circuitry is at least two times greater than a substrate resistance between the power generating circuitry and the ring.

12. A device, comprising:
a chip comprising a power supply and a firing stage, the firing stage being configured to generate a firing signal for an airbag; and
a conductive ring surrounding the power supply and the firing stage, the ring being conductive and being connected with pins of the chip via a plurality of connections.

13. The device of claim 12, wherein the pins of the chip connected to the ring via the plurality of connections are coupled with ground.

14. The device of claim 12, wherein the ring comprises copper.

15. The device of claim 12, wherein the power supply comprises one or more of a buck converter, a boost converter or a linear voltage source.

16. The device of claim 12, further comprising a trench between the power supply and the firing stage.

17. The device of claim 12, the chip further comprising a safing engine that is separated from the rest of the chip by a trench.

18. The device of claim 12, wherein the chip comprising a plurality of firing stages.

19. A method, comprising:
forming power generating circuitry on a substrate;
forming safety-critical circuitry on the substrate; and
forming a conductive ring around the power generating part and the safety-critical circuitry.

20. The method of claim 19, wherein providing the safety-critical circuitry comprises circuitry the safety-critical part at a minimum safety distance from the power generating circuitry, the minimum safety distance determined such that a substrate resistance between the power generating circuitry and the safety-critical circuitry is at least twice as high as a substrate resistance between the power generating part and the ring.

21. The method of claim 19, further comprising providing a barrier between the power generating circuitry and the safety-critical circuitry.

22. The method of claim 19, further comprising forming a plurality of connections between the ring and an external voltage potential.

23. The method of claim 22, further comprising providing one or more connections between the power generating part and an external voltage source, wherein the number connections between the power generating part and the external voltage source is smaller than the number of connections between the ring and the external voltage potential.

24. The method of claim 19, wherein the power generating circuitry comprises a power source and wherein the safety-critical circuitry comprises at least one firing stage for an airbag.
